(19) United States
(12) Patent Application Publication
(10) Pub. No.: US 2011/0242407 A1
(43) Pub. Date: Oct. 6, 2011

(54) CAMERA MODULE AND METHOD FOR MAKING SAME

(75) Inventor: CHUN-YU LEE, Tu-Cheng (TW)

(73) Assignee: HON HAI PRECISION INDUSTRY CO., LTD., Tu-Cheng (TW)

(21) Appl. No.: 12/797,524

(22) Filed: Jun. 9, 2010

(30) Foreign Application Priority Data
Apr. 6, 2010 (TW) 99110485

(51) Int. Cl. H04N 5/225; H05K 13/00

(52) U.S. Cl. 348/374; 29/592.1; 348/E05.024

(57) ABSTRACT

A camera module includes a lens module, an infrared cut film covering the majority of the outer surface of the lens module, a printed circuit board, and a mass of reflowable solder paste attaching the lens module to the print circuit board.

### BACKGROUND

1. Technical Field

The present disclosure relates to optical imaging, and particularly, to a camera module, and a method for making the camera module.

2. Description of Related Art

With the development of optical imaging technology, camera modules are widely used in electronic devices, such as digital cameras, mobile phones, personal digital assistants, etc.

Generally, a lens module with lenses of a camera module is fixed on a substrate of the camera module with solder paste, and the substrate of the camera module is fixed on a main body of a mobile phone. In order to insure the lens module is securely fixed on the substrate, most manufacturers require the camera module to undergo a reflow soldering process. However, due to the higher temperature (i.e. 120 degrees centigrade) in the reflow soldering process, the lenses of the camera module, which are usually made of plastic, can deform. Accordingly, imaging quality of the camera module can be lowered.

Therefore, it is desirable to provide a camera module, and a method for making the camera module, which can overcome the above mentioned limitations.

### BRIEF DESCRIPTION OF THE DRAWINGS

FIG. 1 is a schematic cross-section view of a camera module according to a first embodiment.

FIGS. 2-5 are cross-section views illustrating successive stages in a process for making the camera module of FIG. 1.

FIG. 6 is a schematic cross-section view of a camera module according to a second embodiment.

FIGS. 7-10 are cross-section views illustrating successive stages in a process for making the camera module of FIG. 6.

### DETAILED DESCRIPTION

Embodiments will now be described in detail below with reference to drawings.

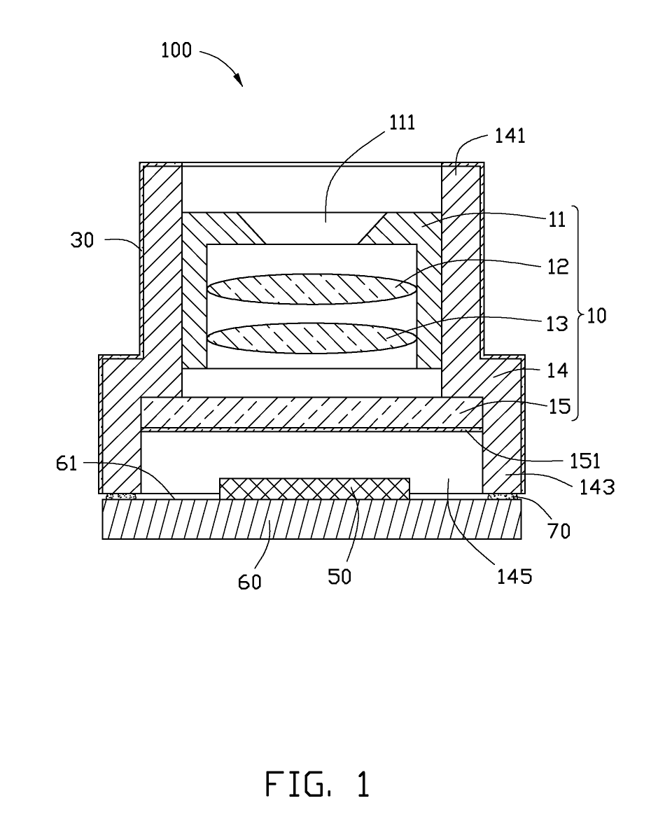

Referring to FIG. 1, a camera module 100 according to a first embodiment is shown. The camera module 100 includes a lens module 10, an infrared cut film 30, an image sensor chip 50, a printed circuit board (PCB) 60, and a mass of reflowable solder paste 70 for attaching the lens module 10 to the PCB 60.

The lens module 10 includes a lens barrel 11, two lenses 12, 13, a lens holder 14 for receiving the lens barrel 11, and an infrared cut member 15 received in the lens holder 14. In this embodiment, the infrared cut member 15 is interposed between the lens barrel 11 and the PCB 60.

The lens barrel 11 is configured for receiving the lenses 12, 13. An aperture 111 is defined in the top end of the lens barrel 11 for allowing light to reach the lenses 12, 13. In other embodiments, there may be one lens or three or more lenses received in the lens barrel 11.

The lens holder 14 has a front end 141 and a rear end 143 opposite to the front end 141. The rear end 143 is securely attached to the PCB 60 with the reflowable solder paste 70. A receiving cavity 145 penetrating/extending through the lens holder 14 from the front end 141 to the rear end 143 is defined in the lens holder 14. The receiving cavity 145 communicates with the aperture 111, and is configured for receiving the lens barrel 11 and the infrared cut optical member 15. In the present embodiment, the lens barrel 11 is entirely received in the receiving cavity 145.

The infrared cut member 15 is received in the receiving cavity 145, and is interposed between the lens barrel 11 and the PCB 60. In the present embodiment, the infrared cut member 15 is a light pervious plate substrate with an infrared cut film 151 formed thereon. In alternative embodiments, the infrared cut member 15 may instead be an infrared cut plate. In further alternative embodiments, the infrared cut member 15 may be a lens with an infrared cut film 151 formed thereon.

The infrared cut film 30 covers the majority of the outer surface of the lens module 10. In other embodiments, the infrared cut film 30 may only cover the outer sidewall of the lens holder 14.

The image sensor chip 50 is directly mounted on the PCB 60. The image sensor chip 50 is configured for converting an optical image from the lens module 10 to an electrical signal.

The PCB 60 is securely mounted on a main body of an electric device (not shown). The PCB 60 includes a top surface 61 for supporting the image sensor chip 50 and the lens holder 14 thereon.

A method for making the camera module 100 will be described in detail.

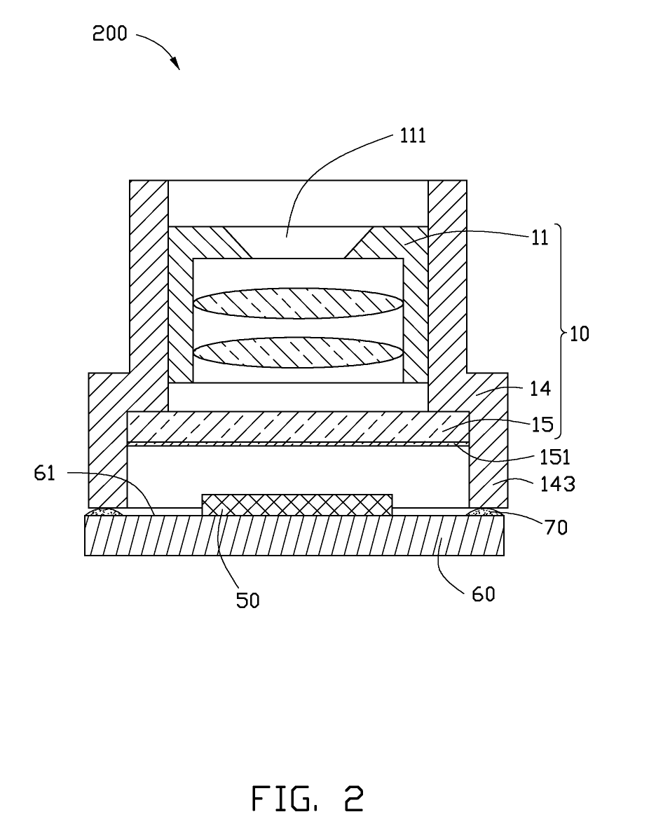

Referring to FIG. 2, a reflowable camera module 200 waiting to be processed is provided first. The reflowable camera module 200 includes the lens module 10, the image sensor chip 50, and the PCB 60. The lens module 10 includes the lens barrel 11 having the aperture 111, the lens holder 14, and the infrared cut member 15 with the infrared cut film 151 formed thereon. The reflowable solder paste 70 is interposed between the rear end 143 of the lens holder 10 and the top surface 61 of the PCB 60.

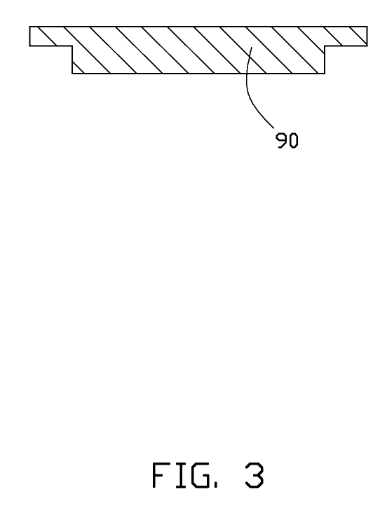

Referring to FIG. 3, a cover 90 for covering the aperture 111 of the lens module 10 is provided.

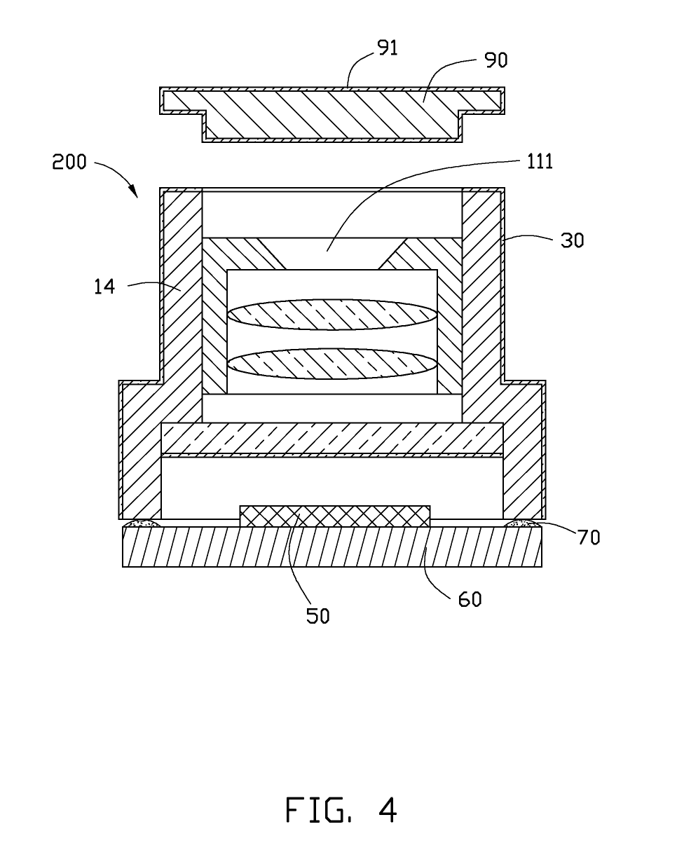

Referring to FIG. 4, the infrared cut film 30 is formed on the majority of the outer surface of the lens holder 14, and an infrared cut film 91 is formed on the outer surface of the cover 90.

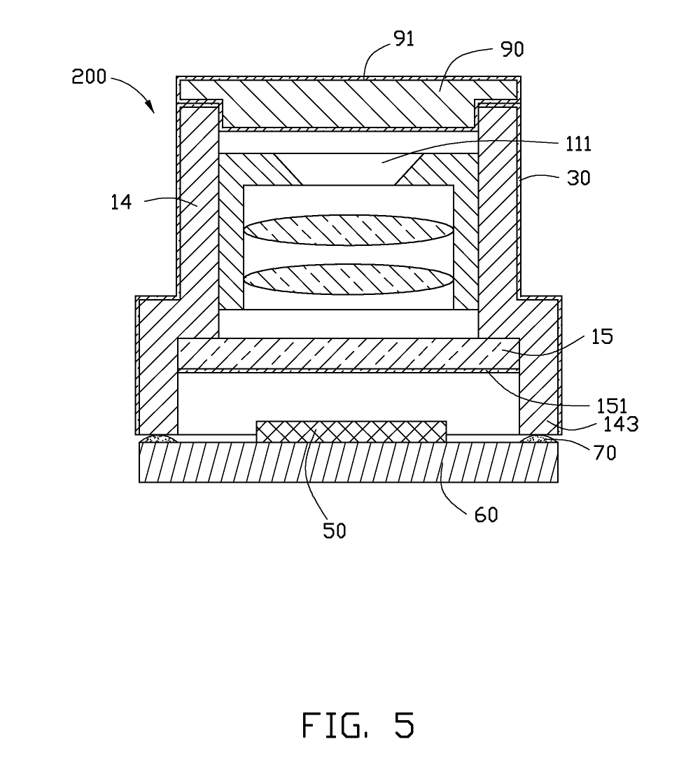

Referring to FIG. 5, the aperture 111 of the lens module 10 is covered by the cover 90. Then, the reflowable camera module 200 with the cover 90 is put into an infrared heating reflow furnace (not shown) to reflow the solder paste 70 using a solder reflowing process, thereby making the reflowable solder paste 70 melt to enlarge contact areas between the rear end 143, the PCB 60 and the reflowable solder paste 70. Next, the reflowable camera module 200 with the cover 90 is cooled to make the rear end 143 of the lens holder 14 become securely attached to the PCB 60.

Finally, the cooled reflowable camera module 200 with the cover 90 is removed from the infrared heating reflow furnace, and then the cover 90 is removed from the cooled reflowable camera module 20 to obtain the camera module 100.

Due to the infrared cut films 151, 30, 91, infrared light from the infrared heating reflow furnace can be effectively reflected, thereby reducing heat reaching the lens module 10. Therefore, the lenses 12, 13 cannot be easily deformed. Accordingly, imaging quality of the camera module 100 can be increased.

In other embodiments, the infrared cut film 30 may only cover the outer sidewall of the lens holder 14. In such a case, the infrared cut films 151, 30, 91, can effectively prevent infrared light from entering into the lens module 10.

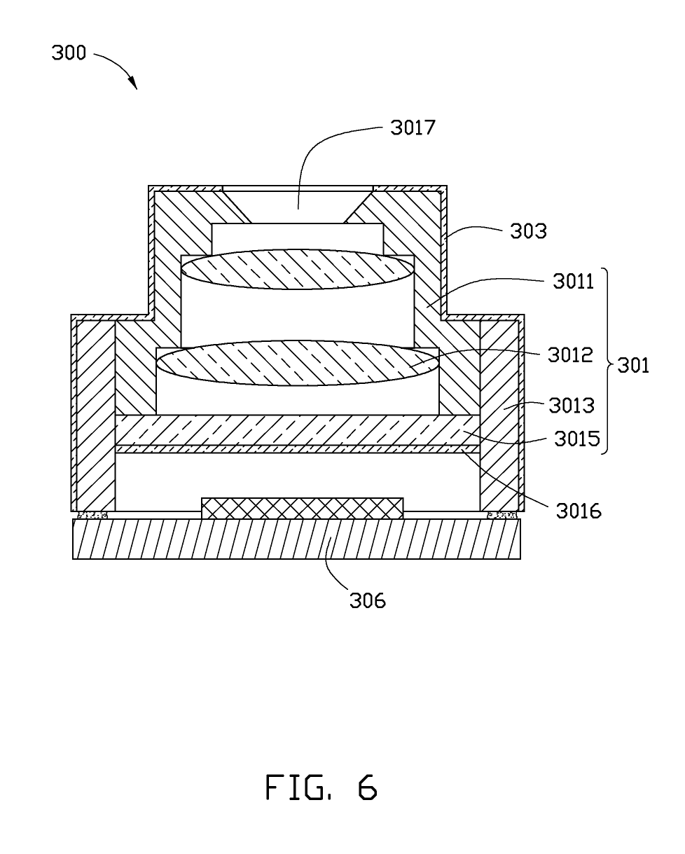

Referring to FIG. 6, a camera module 300, in accordance with a second embodiment, is shown. The camera module 300 includes a lens module 301, an infrared cut film 303, and a printed circuit board (PCB) 306. The lens module 301 includes a lens barrel 3011 with a lens 3012, a lens holder 3013, and an infrared cut member 3015 having an infrared cut film 3016 formed thereon. The lens barrel 3011 is partially received in the lens holder 3013. An aperture 3017 is defined at the top end of the lens barrel 3011 for allowing light to reach lenses 12, 13. The infrared cut film 303 covers the outer surface of the lens module 301. In the present embodiment, a portion of the outer surface of the lens holder 3013, and a portion of the outer surface of the lens barrel 3011 are covered with the infrared cut film 303. In another embodiment, the lens holder 3013 may be omitted. In such a case, the infrared cut member 3015 would be received in the lens barrel 3011 and can be interposed between the lens 3012 and the PCB 306, and the lens barrel 3011 can be attached to the PCB 306.

A method for making the camera module 300 will be described in detail.

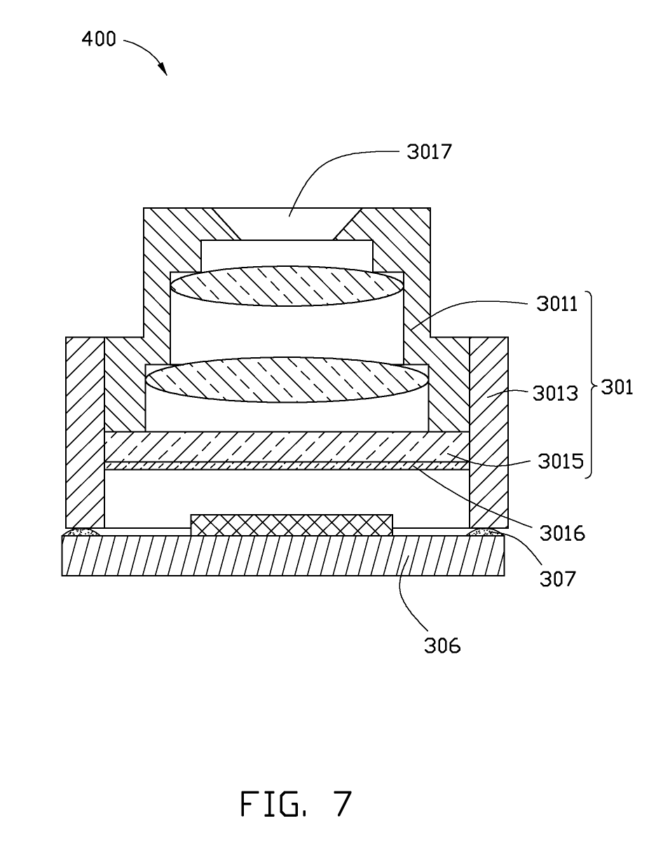

Referring to FIG. 7, a reflowable camera module 400 waiting to be processed is firstly provided. The reflowable camera module 400 includes the lens module 301, the PCB 306, and the reflowable solder paste 307. The lens module 301 includes the lens barrel 3011 having the aperture 3017, the lens holder 3013, and the infrared cut member 3015 with the infrared cut film 3016 formed thereon. The rear end of the lens holder 3013 is attached to the top surface of the PCB 306 by the reflowable solder paste 307.

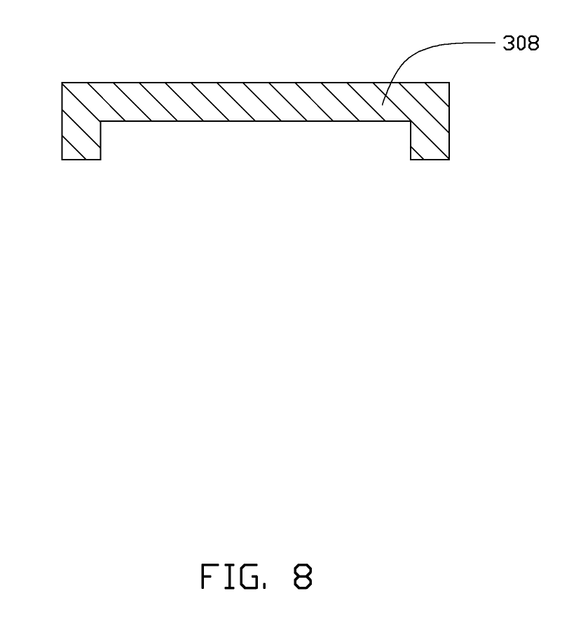

Referring to FIG. 8, a cover 308 for covering aperture 3017 of the lens module 301 is provided. In the present embodiment, the cover 308 is a U-shaped structure.

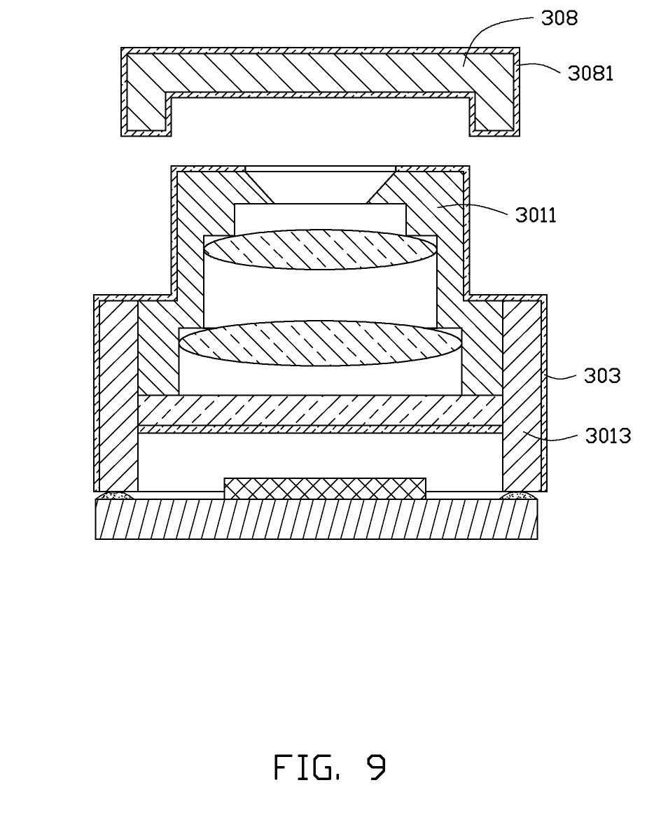

Referring to FIG. 9, a portion of the outer surface of the lens holder 3013, and a portion of the outer surface of the lens barrel 3011 are covered with the infrared cut film 303. The outer surface of the cover 308 is covered with an infrared cut film 3081.

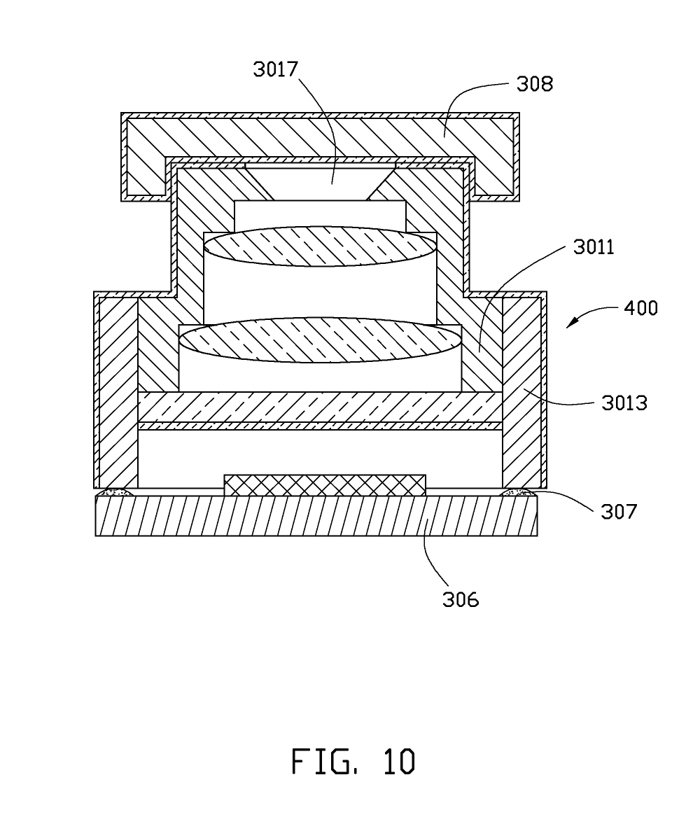

Referring to FIG. 10, the aperture 3017 of the lens barrel 3011 is covered by the cover 308. In the present embodiment, the top end of the lens barrel 3011 is received in the cover 308. Then, the reflowable camera module 400 with the cover 308 is put into the infrared heating reflow furnace to reflow the reflowable solder paste 307 using a solder reflowing process. Next, the reflowable camera module 400 with the cover 308 is cooled to securely attach the rear end of the lens holder 3013 to the PCB 306 by the reflowable solder paste 307.

Finally, the cooled reflowable camera module 400 with the cover 308 is removed from the infrared heating reflow furnace, and then the cover 308 is removed from the cooled reflowable camera module 400 to obtain the camera module 300.

While certain embodiments have been described and exemplified above, various other embodiments will be apparent to those skilled in the art from the foregoing disclosure. The disclosure is not limited to the particular embodiments described and exemplified but is capable of considerable variation and modification without departure from the scope and spirit of the appended claims.

What is claimed is:

1. A camera module comprising:
a lens module;
an infrared cut film covering the majority of the outer surface of the lens module;
a printed circuit board, and
a mass of reflowable solder paste attaching the lens module to the print circuit board.

2. The camera module of claim 1, wherein the lens module comprises a lens barrel, a lens received in the lens barrel, and an infrared cut member received in the lens barrel and interposed between the lens and the printed circuit board, the infrared cut film covering the outer surface of the lens barrel.

3. The camera module of claim 2, wherein the infrared cut member comprises a lens, and an infrared cut film formed on the lens.

4. The camera module of claim 2, wherein the infrared cut member comprises a plate substrate and an infrared cut film formed on the plate substrate.

5. The camera module of claim 1, wherein the lens module comprises a lens barrel, a lens holder having a receiving cavity, and an infrared cut member, the receiving cavity receiving the lens barrel and the infrared cut member, the infrared cut member interposed between the lens barrel and the printed circuit board.

6. The camera module of claim 5, wherein the lens barrel is partially received in the receiving cavity, the infrared cut film covering a portion of the outer surface of the lens holder, and a portion of the outer surface of the lens barrel.

7. The camera module of claim 6, wherein the infrared cut member comprises a lens, and an infrared cut film formed on the lens.

8. The camera module of claim 6, wherein the infrared cut member comprises a plate substrate and an infrared cut film formed on the plate substrate.

9. The camera module of claim 5, wherein the lens barrel is entirely received in the receiving cavity, and the infrared cut film covering the outer surface of the lens holder.

10. The camera module of claim 9, wherein the infrared cut member comprises a lens, and an infrared cut film formed on the lens.

11. The camera module of claim 9, wherein the infrared cut member comprises a plate substrate and an infrared cut film formed on the plate substrate.

12. A camera module comprising:
a lens module;
an infrared cut film formed on the outer sidewall of the lens module;
a printed circuit board, and
a mass of reflowable solder paste attaching the lens module to the print circuit board.

13. The camera module of claim 12, wherein the lens module comprises a lens barrel, a lens received in the lens barrel, and an infrared cut member received in the lens barrel and interposed between the lens and the printed circuit board, the infrared cut film covering the outer sidewall of the lens barrel.

14. The camera module of claim 12, wherein the lens module comprises a lens barrel, a lens holder having a receiving cavity, and an infrared cut member, the receiving cavity receiving the lens barrel and the infrared cut member, the infrared cut member interposed between the lens barrel and the printed circuit board.

15. The camera module of claim 14, wherein the lens barrel is partially received in the receiving cavity, the infrared cut film covering a portion of the outer surface of the lens holder, and a portion of the outer surface of the lens barrel.

16. The camera module of claim 14, wherein the lens barrel is entirely received in the receiving cavity, and the infrared cut film covering the outer sidewall of the lens holder.

17. A method for making a camera module comprising:
providing a reflowable camera module, the reflowable camera module comprising a lens module having an aperture for allowing light to enter into the lens module, a printed circuit board, and a mass of reflowable solder paste interposed between the lens module and the printed circuit board;
providing a cover for covering the aperture;
forming infrared cut films on the majority of the outer surface of the lens module, and the outer surface of the cover;
covering the aperture by the cover with the infrared cut film;
reflowing the reflowable solder paste using a solder reflowing process, thereby attaching the lens module to the printed circuit board;
removing the cover from the reflowable camera module.

18. The method of claim 17, further comprising: cooling the reflowable camera with the cover prior to removing the cover from the reflowable camera module.

19. The method of claim 17, wherein the lens module comprises a lens barrel, a lens holder having a receiving cavity, and an infrared cut member, the receiving cavity receiving the lens barrel and the infrared cut member, the infrared cut member interposed between the lens barrel and the printed circuit board.

20. The method of claim 19, wherein the lens barrel is partially received in the receiving cavity, the infrared cut film covering a portion of the outer surface of the lens holder, and a portion of the outer surface of the lens barrel.
